(19) United States
(12) Patent Application Publication
(10) Pub. No.: US 2013/0219708 A1
(43) Pub. Date: Aug. 29, 2013

(54) MOUNTING HEAD UNIT, COMPONENT MOUNTING APPARATUS, AND METHOD OF MANUFACTURING A SUBSTRATE

(71) Applicant: SONY CORPORATION, (US)

(72) Inventors: Yousuke Komatsu, Saitama (JP); Tadahiro Satoh, Kanagawa (JP)

(73) Assignee: SONY CORPORATION, Tokyo (JP)

(21) Appl. No.: 13/773,026

(22) Filed: Feb. 21, 2013

(30) Foreign Application Priority Data
Feb. 28, 2012 (JP) 2012-041130

(51) Int. Cl. H05K 3/30

(52) U.S. Cl. CPC H05K 3/30
USPC 29/739

(57) ABSTRACT

A mounting head unit includes a rotating body, a nozzle, and a valve mechanism. The rotating body includes a rotating shaft, a negative-pressure path provided within the rotating shaft to flow negative-pressure gas therethrough, a non-negative-pressure path for flowing non-negative-pressure gas therethrough, which is provided within the rotating shaft to be aligned with the negative-pressure path in an axial direction of the rotating shaft, and a partition provided within the rotating shaft to partition the negative-pressure and non-negative-pressure paths. The nozzle includes a flow path for flowing gas therethrough, is connected to the rotating body such that the flow path is in communication with the negative-pressure and non-negative-pressure paths of the rotating body, and is capable of sucking a component by being supplied with the negative-pressure gas from the negative-pressure path. The valve mechanism switches between negative-pressure and non-negative-pressure states of the gas to be supplied into the nozzle.

### BACKGROUND

The present disclosure relates to a component mounting apparatus that mounts an electronic component on a substrate, to a mounting head unit to be used in the same, and to a method of manufacturing such a substrate.

Japanese Patent No. 3772372 (hereinafter, referred to as Patent Document 1) describes a component attachment apparatus (component mounting apparatus) using a tool head. In this component attachment apparatus, the tool head includes a plurality of suction nozzles that suck and retain electronic components. The tool head is configured to be movable, above a substrate being a target on which electronic components are to be mounted, in a plane parallel to a mounting surface of the substrate. The plurality of suction nozzles are installed around a head portion fixed to a lower side of a base shaft. The tool head includes a mechanism in which the plurality of suction nozzles are supplied with positive-pressure air and negative-pressure air. The plurality of suction nozzles retain electronic components one by one by being supplied with the negative-pressure air and mount the retained electronic components on the substrate by being supplied with the positive-pressure air.

For example, upon mounting of the electronic components on the substrate, the tool head rotates a head portion by a predetermined rotational angle. With this, the tool head selects the plurality of suction nozzles sequentially one by one and mounts each of the electronic components retained by the suction nozzles on, for example, a single substrate.

In the tool head of Patent Document 1, in order to individually form positive-pressure and negative-pressure paths, a tubular member is provided within the base shaft of the tool head. Specifically, the positive-pressure air is supplied into the tubular member and the negative-pressure air is supplied into the base shaft outside the tubular member.

### SUMMARY

However, there is a problem in that the tool head described in Patent Document 1 has a complicated structure.

Therefore, it is desirable to provide a mounting head unit having a relatively simple structure, a component mounting apparatus using the same, and a method of manufacturing a substrate.

According to an embodiment of the present disclosure, there is provided a mounting head unit including a rotating body, a nozzle, and a valve mechanism.

The rotating body includes a rotating shaft, a negative-pressure path, a non-negative-pressure path, and a partition.

The negative-pressure path is provided within the rotating shaft and configured to flow negative-pressure gas therethrough.

The non-negative-pressure path is configured to flow non-negative-pressure gas therethrough and provided within the rotating shaft to be aligned with the negative-pressure path in an axial direction of the rotating shaft.

The partition is provided within the rotating shaft and configured to separate the negative-pressure path from the non-negative-pressure path.

The nozzle includes a flow path configured to flow gas therethrough, is connected to the rotating body such that the flow path is in communication with the negative-pressure path and the non-negative-pressure path of the rotating body, and configured to be capable of sucking a component by being supplied with the negative-pressure gas from the negative-pressure path.

The valve mechanism is configured to switch between a negative-pressure state and a non-negative-pressure state of the gas to be supplied into the nozzle.

In the embodiment of the present disclosure, the negative-pressure path and the non-negative-pressure path are aligned with each other in the axial direction of the rotating shaft of the rotating body. Therefore, the negative-pressure gas and the non-negative-pressure gas are supplied from part of the rotating shaft and another part spaced from the part to the negative-pressure path and the non-negative-pressure path, respectively. That is, in the embodiment of the present disclosure, unlike the related art, it is necessary to insert a tubular member into the base shaft to separate the negative-pressure path from the non-negative-pressure path in the radial direction of the shaft, and hence the structure of the mounting head unit can be simplified.

The rotating shaft of the rotating body may include a first end portion, and a second end portion on an opposite side of the first end portion. Further, the mounting head unit may further include a support configured to integrally support the first end portion and the second end portion of the rotating shaft.

The support integrally supports the first end portion and the second end portion of the rotating shaft, and hence backlash of the rotating shaft can be reduced.

The support may include a first support portion and a second support portion.

The first support portion includes a supply path of the negative-pressure gas and is connected to the first end portion of the rotating shaft, the supply path of the negative-pressure gas being in communication with the negative-pressure path of the rotating shaft.

The second support portion includes a supply path of the non-negative-pressure gas and is connected to the second end portion of the rotating shaft, the supply path of the non-negative-pressure gas being in communication with the non-negative-pressure path of the rotating shaft.

With this, the support that reduces backlash of the rotating shaft can supply the negative-pressure gas and the non-negative-pressure gas from the supply paths to the negative-pressure path and the non-negative-pressure path within the rotating shaft, respectively.

The rotating body may be formed such that the negative-pressure path has a volume larger than a volume of the non-negative-pressure path. With this, suction response of a component using a negative pressure of the nozzle can be enhanced.

The rotating shaft of the rotating body may include a through-hole along the axial direction of the rotating shaft. Further, the rotating body may further include a tubular body including the partition, the tubular body being located to be closer to the first end portion than the second end portion within the through-hole of the rotating shaft.

By inserting the tubular body into the rotating shaft, the rotating body including the negative-pressure path, the non-negative-pressure path, and the partition can be manufactured, which is easy.

The negative-pressure path and the non-negative-pressure path may be coaxially arranged. With this, the rotating shaft can be made thinner and downsizing of the rotating body can be achieved.

The valve mechanism includes a casing and a valve body.

In this case, the casing includes a connection path that is connected to the negative-pressure path and the non-negative-pressure path and capable of supplying the negative-pressure gas and the non-negative-pressure gas to the nozzle. The casing is connected to the rotating body.

Further, the valve body is provided within the casing and configured to switch between communication of the negative-pressure path with the connection path of the casing and communication of the non-negative-pressure path with the connection path.

The mounting head unit may further include a second rotating body that includes an engagement portion and is rotatably connected to an outer peripheral portion of the rotating shaft. In this case, the rotating body may include an engagement portion that is engaged to the engagement portion of the second rotating body and retain the nozzle to be rotatable by rotation of the second rotating body.

The rotation of the second rotating body can rotate the nozzle via the engagement portion.

The mounting head unit may further include a plurality of nozzles. In this case, the engagement portion may include a plurality of engagement portions respectively provided for the plurality of nozzles, the plurality of engagement portions offsetting each other in length directions of the plurality of nozzles.

With this, arrangement density of the plurality of nozzles can be increased and downsizing of the mounting head unit can be achieved.

The rotating body may include a turret configured to support a plurality of nozzles, the turret including part of each of the non-negative-pressure path and the negative-pressure path and being provided to an end portion of the rotating shaft.

According to another embodiment of the present disclosure, there is provided a component mounting apparatus including a retaining unit configured to retain a substrate and the above-mentioned mounting head unit configured to mount a component on the substrate retained by the retaining unit.

According to still another embodiment of the present disclosure, there is provided a method of manufacturing a substrate by the above-mentioned component mounting apparatus.

A component is sucked by a nozzle supplied with the negative-pressure gas from a negative-pressure path.

The sucked component is mounted on the substrate retained by a retaining unit, by supplying non-negative-pressure gas from non-negative-pressure path to the nozzle.

As described above, according to the embodiments of the present disclosure, it is possible to provide a mounting head unit having a relatively simple structure.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a schematic front view showing a component mounting apparatus according to an embodiment of the present disclosure;

FIG. 2 is a plan view of the component mounting apparatus shown in FIG. 1;

FIG. 3 is a side view of the component mounting apparatus shown in FIG. 1;

FIG. 4 is a cross-sectional view showing a configuration of a mounting head unit according to a first embodiment;

FIG. 5 is a perspective view mainly showing a turret and a plurality of nozzles;

FIGS. 6A and 6B are schematic cross-sectional views each showing a valve mechanism, which are taken along the line A-A of FIG. 4;

FIG. 7 is a cross-sectional view showing a nozzle retained by the turret;

FIG. 8 is a cross-sectional view showing a state in which the nozzle moves downwards;

FIG. 9 is a view showing an operation of the valve mechanism, more specifically, a view showing a state in which a valve main body is located at an initial position;

FIG. 10 is a view showing an operation of the valve mechanism, more specifically, a view showing a state in which a negative-pressure path is opened;

FIG. 11 is a view showing an operation of the valve mechanism, more specifically, a view showing a state in which the valve main body is located at the initial position;

FIG. 12 is a view showing an operation of the valve mechanism, more specifically, a view showing a state in which a positive-pressure path is opened; and

FIG. 13 is a cross-sectional view showing a configuration of a mounting head unit according to a second embodiment.

### DETAILED DESCRIPTION OF EMBODIMENTS

### Configuration of Component Mounting Apparatus

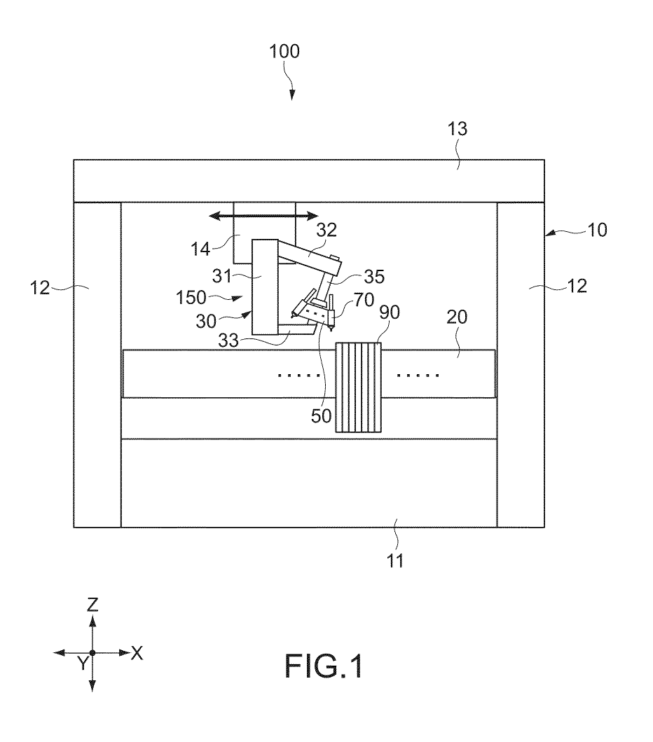

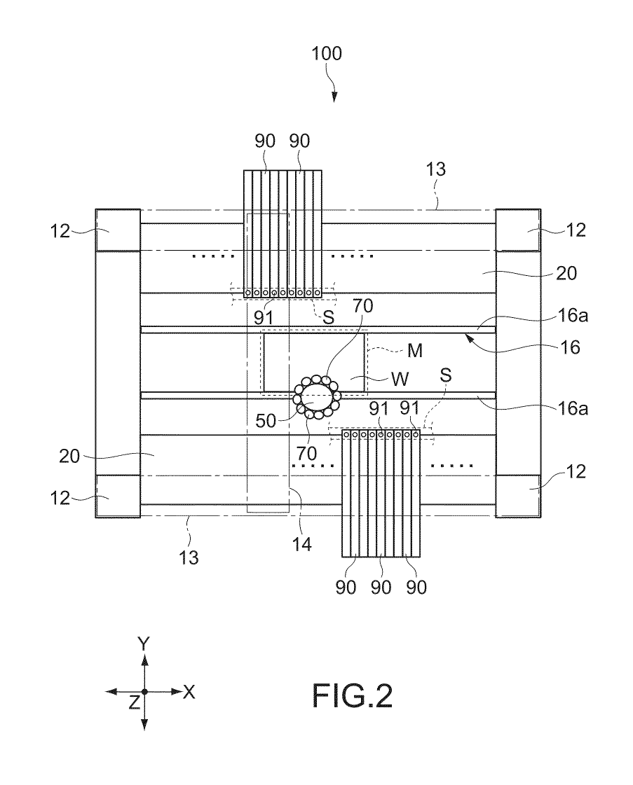

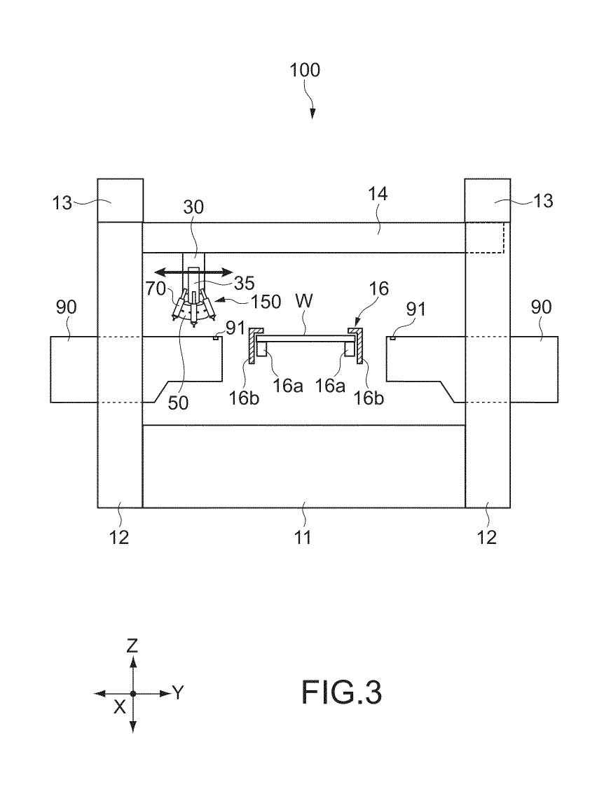

FIG. 1 is a schematic front view showing a component mounting apparatus according to an embodiment of the present disclosure. FIG. 2 is a plan view of a component mounting apparatus 100 shown in FIG. 1. FIG. 3 is a side view of the component mounting apparatus 100.

The component mounting apparatus 100 includes a frame 10, a mounting head unit 150, and tape feeder installation portions 20. The mounting head unit 150 retains an electronic component (not shown) and mounts the electronic component on a circuit substrate W (hereinafter, abbreviated as substrate) that is a mounting target. Tape feeders 90 are installed in the tape feeder installation portions 20. Further, the component mounting apparatus 100 includes a conveyor unit 16 (see FIG. 2) that retains and conveys the substrate W.

The frame 10 includes a base 11 provided at a bottom and a plurality of support columns 12 fixed to the base 11. Upper portions of the plurality of support columns 12 are provided with, for example, two X-beams 13 along an X-axis in the figure. For example, between the two X-beams 13, a Y-beam 14 is provided along a Y-axis. The mounting head unit 150 is connected to the Y-beam 14. The X-beams 13 and the Y-beam 14 are equipped with an X-axis movement mechanism and a Y-axis movement mechanism (not shown), respectively. Those movement mechanisms allow the mounting head unit 150 to move along the X-axis and the Y-axis. Although the X-axis movement mechanism and the Y-axis movement mechanism are typically constituted of ball-screw driving mechanisms, other mechanisms such as a belt driving mechanism may be employed.

A plurality of mounting head units 150 may be provided mainly for increasing productivity. In this case, the plurality of mounting head units 150 are independently driven in an X-axis direction and a Y-axis direction.

As shown in FIG. 2, the tape feeder installation portions 20 are provided on both of a front side (lower side in FIG. 2) and a rear side (upper side in FIG. 2) of the component mounting apparatus 100. The Y-axis direction in the figures is front and rear directions of the component mounting apparatus 100. In each of the tape feeder installation portions 20, the plurality of tape feeders 90 are arranged and installed along the X-axis direction. For example, 40 to 70 tape feeders 90 may be installed in the tape feeder installation portion. In this embodiment, a total of 116 tape feeders 90 (58 tape feeders on the front side and 58 tape feeders on the rear side) may be installed.

Note that, although the tape feeder installation portions 20 are provided on both of the front side and the rear side of the component mounting apparatus 100, the tape feeder installation portions 20 may be provided on either one of the front side and the rear side.

The tape feeder 90 is formed to be long in Y-axis direction. Although not shown in the drawings in detail, the tape feeder 90 includes a reel, and a carrier tape housing electronic components such as a capacitor, a resistor, a light-emitting diode (LED), and integrated circuit (IC) packaging is wound around the reel. Further, the tape feeder 90 includes a mechanism for feeding the carrier tape in a stepwise manner. For each stepwise feeding, the electronic components are fed one by one. As shown in FIG. 2, a supply window 91 is formed in an upper surface of an end portion of a cassette of the tape feeder 90. Through the supply window 91, the electronic components are supplied. An area in which the plurality of supply windows 91 are arranged, which is formed along the X-axis direction when the plurality of tape feeders 90 are arranged, serves as a supply area S of electronic components.

Note that, in the carrier tape of one of the tape feeders 90, a large number of the same kind of electronic components are housed. Out of the tape feeders 90 to be installed in the tape feeder installation portion 20, a plurality of continuous tape feeders 90 may house the same kind of electronic components.

The conveyor unit 16 is provided at a center portion of the component mounting apparatus 100 in the Y-axis direction. The conveyor unit 16 coveys the substrate W along the X-axis direction. For example, as shown in FIG. 2, an area of the conveyor unit 16 at an almost center position in the X-axis direction, on which the substrate W is supported by the conveyor unit 16, serves as a mounting area M. The mounting area M is an area in which mounting of the electronic component is performed by the mounting head unit 150 accessing the area.

The component mounting apparatus 100 detects an exact position of the substrate W conveyed to the mounting area M using a substrate camera (not shown). After the exact position of the substrate W is detected, the mounting head unit 150 starts a mounting operation of the electronic component. The substrate camera is connected to the X-axis movement mechanism and the Y-axis movement mechanism and is movable integrally with the mounting head unit 150.

Although will be described later in detail, the mounting head unit 150 includes a support 30, a base shaft 35, and a turret 50. The support 30 is connected to the Y-axis movement mechanism of the Y-beam 14. The base shaft 35 serves as a main rotating shaft supported by the support 30. The turret 50 is fixed to a lower end portion of the base shaft 35. Further, the mounting head unit 150 includes a plurality of nozzle units 70 connected to an outer peripheral portion of the turret 50. For example, 12 nozzle units 70 are provided.

Note that, the support 30 may be connected to the X-axis movement mechanism. In this case, the Y-axis movement mechanism moves the X-axis movement mechanism and the mounting head unit 150 along the Y-axis direction.

The base shaft 35 is provided while being inclined with respect to a vertical axis (Z-axis). The base shaft 35 and the turret 50 are capable of integrally rotating with the base shaft 35 being a center axis of rotation. Out of the plurality of nozzle units 70, the nozzle unit 70 located having a length direction along a Z-axis direction serves as a nozzle unit 70A selected for mounting the electronic component on the substrate W. By rotation of the turret 50, one nozzle unit 70A is arbitrarily selected. The selected nozzle unit 70A accesses the supply window 91 of the tape feeder 90, sucks and retains an electronic component, moves to above the mounting area M, and then moves downwards. In this manner, the electronic component is mounted on the substrate W.

The mounting head unit 150 is movable in the X-axis direction and the Y-axis direction as described above. The nozzle units 70 move between the supply area S and the mounting area M. Further, the nozzle unit 70 moves in the X-axis direction and the Y-axis direction within the mounting area M in order to perform mounting in the mounting area M.

While rotating the turret 50, the mounting head unit 150 causes the plurality of nozzle units 70 to retain the plurality of electronic components continuously in a single step. Further, the plurality of electronic components sucked by the plurality of nozzle units 70 are sequentially mounted on one substrate W.

Although the conveyor unit 16 is typically a belt type conveyor, the present disclosure is not limited thereto and any conveyor unit may be employed. For example, a roller type, a type in which a supporting mechanism that supports the substrate W moves slidably, or a non-contact type may be employed. The conveyor unit 16 includes belt portions 16a and guide rails 16b laid along the X-axis direction. Due to the provision of the guide rails 16b, the substrate W is conveyed with misalignment of the conveyed substrate W while the Y-axis direction is corrected.

A lifting and lowering mechanism (not shown) is connected to the belt portions 16a. The substrate W is placed on the belt portions 16a. In this state, by lifting the belt portions 16a in the mounting area M, the substrate W is retained while being sandwiched between the belt portions 16a and the guide rails 16b. In this case, the belt portions 16a and the guide rails 16b function as the retaining unit for a substrate. In other words, the retaining unit forms part of the conveyor unit 16.

### Configuration of Mounting Head Unit According to First Embodiment

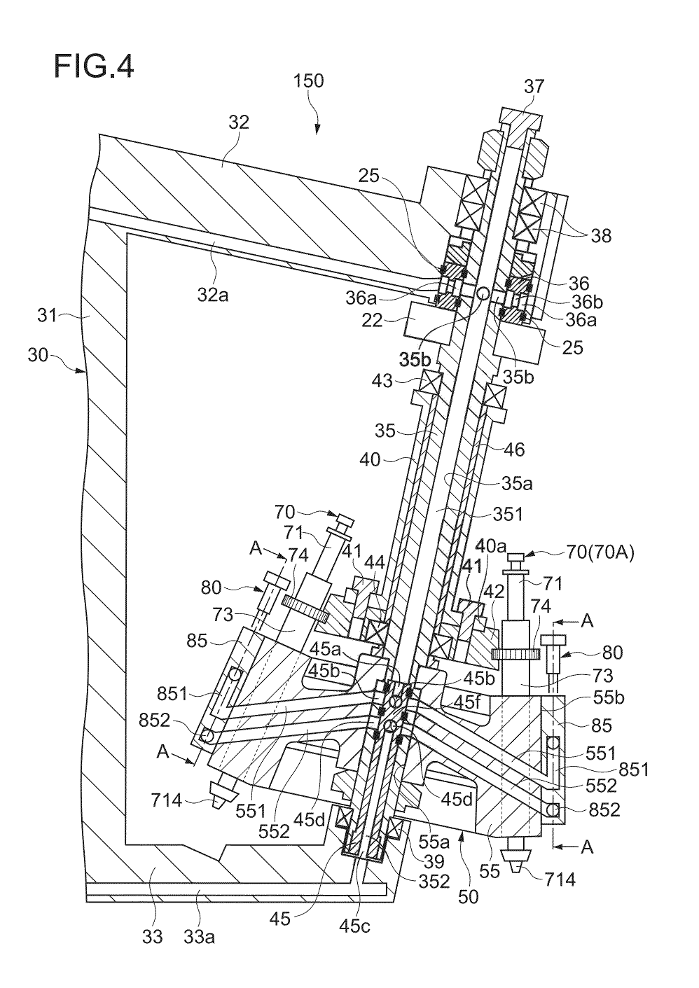

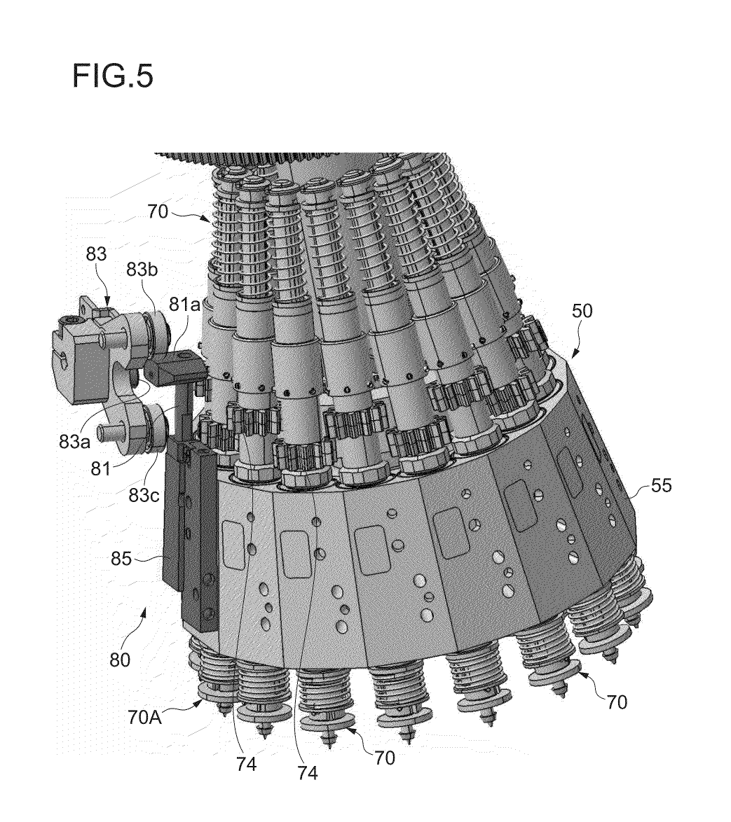

FIG. 4 is a cross-sectional view showing a configuration of the mounting head unit 150 according to the first embodiment. FIG. 5 is a perspective view mainly showing the turret 50 and the plurality of nozzle units 70.

Referring to FIG. 4, the mounting head unit 150 includes, as described above, the support 30 connected to the Y-axis movement mechanism of the Y-beam 14. The support 30 includes an upper support portion 32 (second support portion) and a lower support portion 33 (first support portion). The upper support portion 32 rotatably supports an upper portion (first end portion) of the base shaft 35 via a bearing 38. The lower support portion 33 rotatably supports a lower portion (second end portion) of the base shaft 35 via a bearing 39. A pulley 22 is fixed to a portion of the base shaft 35 that is located on the lower side of the upper support portion 32. Although not shown in the drawings, a motor is connected to the pulley 22 via a belt. With this, the base shaft 35 is driven to rotate.

In the upper support portion 32, there is formed a negative-pressure supply path 32a being a supply path of negative-pressure air, that is, the air having a lower pressure than an atmospheric pressure. For example, a tube and a pump (not shown) are connected to the negative-pressure supply path 32a. The negative-pressure supply path 32a is supplied with negative-pressure air as negative-pressure gas. Note that, “supply the negative-pressure air” means that the airflows from each negative-pressure flow path to the pump as an airflow.

On the other hand, in the lower support portion 33, a positive-pressure supply path 33a is formed. For example, a tube and a pressurizing mechanism (not shown) are connected to the positive-pressure supply path 33a. The positive-pressure supply path 33a is supplied with, for example, positive-pressure air having a pressure higher than the atmospheric pressure, as non-negative-pressure gas.

Inside the base shaft 35, a through-hole 35a is formed along an axial direction thereof. A cap 37 for hermetically sealing the through-hole 35a is attached to an upper end of the base shaft 35.

For example, a manifold 36 including flow paths in radial directions (radial flow paths) is connected between the upper portion of the base shaft 35 and the upper support portion 32. For example, the manifold 36 includes four radial flow paths 36b at 90-degree intervals. Further, the manifold 36 includes, in an inner peripheral surface and an outer peripheral surface of a tubular portion thereof, circumferential grooves 36a formed in a circumferential direction. The circumferential grooves 36a are in communication with the radial flow paths 36b. Via the radial flow paths 36b and the circumferential grooves 36a, the negative-pressure supply path 32a of the upper support portion 32 is in communication with the through-hole 35a in the base shaft 35.

Packing 25 slidable in the circumferential direction are attached to the inner peripheral surface and the outer peripheral surface of the tubular portion of the manifold 36. The manifold 36 is rotatable with respect to the upper support portion 32 and the base shaft 35 while keeping the air flow paths hermetically sealed. Note that, the manifold 36 may be fixed to the upper support portion 32, for example.

As described above, the turret 50 retaining the plurality of nozzle units 70 is fixed to the lower portion of the base shaft 35. Mainly the base shaft 35 and the turret 50 constitute a rotating body.

An outer peripheral surface 55b of a main body 55 of the turret 50 is formed in a tapered shape. For example, negative-pressure paths 551 and positive-pressure paths 552 (non-negative-pressure paths) are formed within the main body 55, the positive-pressure paths 552 being formed below the negative-pressure paths 551. The negative-pressure paths 551 and the positive-pressure paths 552 are formed to extend obliquely with respect to the axial direction of the base shaft 35 and penetrate from an inner peripheral surface 55a of the main body 55 to the outer peripheral surface 55b. Further, the plurality of negative-pressure paths 551 and positive-pressure paths 552 (corresponding to the number of the nozzle units 70) are provided radially as viewed in the axial direction of the base shaft 35.

A tubular body 45 is inserted and fitted in a lower portion of the through-hole 35a of the base shaft 35. The tubular body 45 is provided inside the main body 55 of the turret 50. A lower end surface of the tubular body 45 substantially corresponds to a lower end surface of the base shaft 35.

The tubular body 45 divides the air flow path of the through-hole 35a into a negative-pressure path 351 and a positive-pressure path 352. For example, the tubular body 45 includes an axial negative-pressure flow path 45a forming part of the negative-pressure path 351 within the base shaft 35, and an axial positive-pressure flow path 45c forming part or the whole of the positive-pressure path 352 within the base shaft 35. The tubular body 45 further includes radial flow paths (radial negative-pressure flow paths 45b) in communication with the axial negative-pressure flow path 45a, and radial positive-pressure flow paths 45d in communication with the axial positive-pressure flow path 45c. A partition 45f is formed between the radial negative-pressure flow paths 45b and the radial positive-pressure flow paths 45d.

The three radial negative-pressure flow paths 45b and the three radial positive-pressure flow paths 45d are provided at, for example, 120-degree intervals. Alternatively, two radial negative-pressure flow paths 45b and two radial positive-pressure flow paths 45d or four or more radial negative-pressure flow paths 45b and four or more radial positive-pressure flow paths 45d may be provided.

The flow path formed by the through-hole 35a of the base shaft 35 is in communication with the negative-pressure paths 551 of the main body 55 of the turret 50 via the axial negative-pressure flow path 45a and the radial negative-pressure flow paths 45b of the tubular body 45. Further, the flow path below the lower end of the base shaft 35, that is, the positive-pressure supply path 33a provided in the lower support portion 33 is in communication with the positive-pressure paths 552 of the main body 55 via the axial positive-pressure flow path 45c and the radial positive-pressure flow paths 45d of the tubular body 45. With this, the negative-pressure path 351 and the positive-pressure path 352 are formed within the base shaft 35.

With the above-mentioned configuration, the partition 45f of the tubular body 45 separates the negative-pressure path 351 from the positive-pressure path 352 within the base shaft 35. The negative-pressure path 351 and the positive-pressure path 352 are provided to be aligned with each other in the axial direction. Typically, the negative-pressure path 351 and the positive-pressure path 352 are coaxially arranged.

Further, the base shaft 35 and the turret 50 are formed such that the volume of all of the negative-pressure flow paths within the base shaft 35 and the turret 50 is larger than the volume of all of the positive-pressure flow paths. In this embodiment, out of the base shaft 35 and the turret 50, substantially only the base shaft 35 is formed to have such a structure. With this, as will be described later, suction response of an electronic component using negative pressure of the nozzle unit 70 can be enhanced.

The mounting head unit 150 further includes valve mechanisms 80 that switch between a negative-pressure state and a non-negative-pressure state of the air to be supplied into the nozzle units 70.

As shown in FIG. 5, each of the valve mechanisms 80 includes a casing 85, a valve main body 81, and a valve lever 83. The casing 85 is connected to the outer peripheral surface 55b of the main body 55 of the turret 50. The valve main body 81 is connected to the casing 85. The valve lever 83 drives the valve main body 81.

The casings 85 and the valve main bodies 81 are arranged in the circumferential direction on the outer peripheral surface 55b of the turret 50, corresponding to the number of nozzle units 70. In FIG. 5, one casing 85 and one valve main body 81 are shown and other casings 85 and valve main bodies 81 are omitted.

One valve lever 83 is provided at a position at which the valve lever 83 can drive the valve main body 81 provided to the casing 85 corresponding to one nozzle unit 70A (nozzle unit oriented in Z-axis direction) that is selected for mounting the electronic component. In other words, a plurality of valve levers 83 are not provided.

The valve lever 83 has an almost U-shape, an almost V-shape, or an almost Y-shape. The valve lever 83 includes two abutting rollers 83b and 83c. The valve lever 83 is positioned such that the abutting rollers 83b and 83c sandwiches a head 81a of the valve main body 81. The valve lever 83 is supported by, for example, the support 30 to move integrally with the mounting head unit 150.

The valve lever 83 is connected to a driving source (not shown) and configured to rotate by an amount corresponding to a predetermined angle with a rotating shaft 83a being a center. Due to the rotation of the valve lever 83 by the predetermined angle, an upper abutting roller 83b downwardly pushes the head 81a of the valve main body 81 or the lower abutting roller 83c upwardly pushes the head 81a.

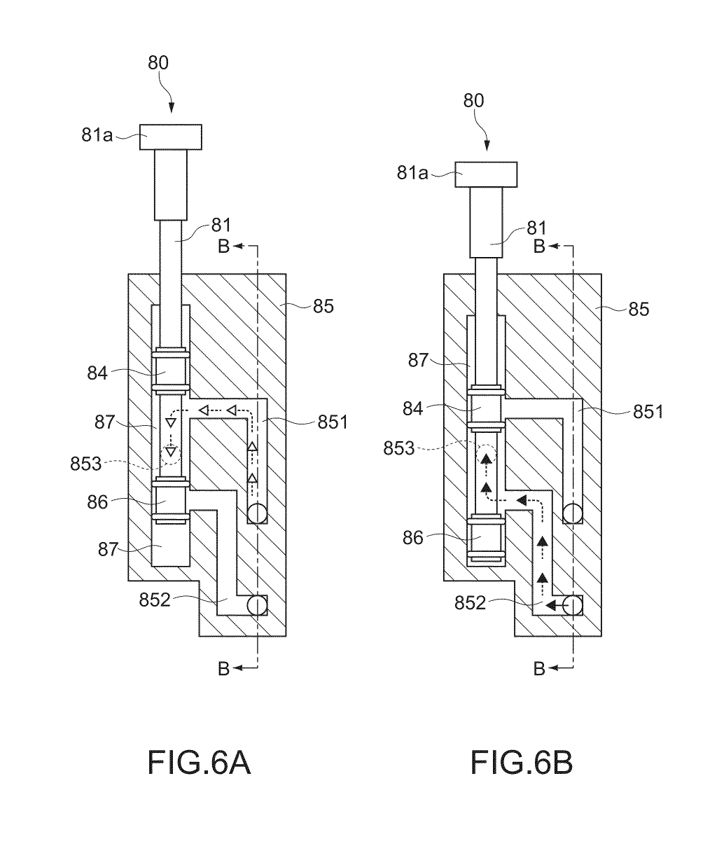

FIG. 6A is a schematic cross-sectional view showing the valve mechanisms 80, which is taken along the line A-A of FIG. 4. A cross-sectional view taken along the line B-B of each of FIGS. 6A and 6B corresponds to the cross-sectional view of FIG. 4.

As shown in FIGS. 4 and 6A, in the casing 85, a negative-pressure path 851 connected to the negative-pressure paths 551 of the turret 50 is formed. Further, a positive-pressure path 852 connected to the positive-pressure paths 552 of the turret 50 is formed. The negative-pressure path 851 of the casing 85 is provided to be bent by, for example, 90 degrees twice from an inlet to an outlet thereof. Similarly, the positive-pressure path 852 is provided to be, for example, bent by 90 degrees twice from an inlet to an outlet thereof.

The valve mechanism 80 is constituted of, for example, a spool valve. An actuating chamber 87 housing two valve bodies 84 and 86 of the valve main body 81 is formed in the casing 85. Outlets of the negative-pressure path 851 and the positive-pressure path 852 are connected to the actuating chamber 87. The actuating chamber 87 is connected to a connection path 853. The connection path 853 is formed in the casing 85 to be in communication with the actuating chamber 87 between the two valve bodies 84 and 86. The connection path 853 is in communication with an actuating chamber 71a provided within a nozzle 71 of the nozzle units 70 as will be described later.

In FIG. 6A, a valve body 86 cuts off the positive-pressure path 852 and opens the negative-pressure path 851. In FIG. 6B, a valve body 84 cuts off the negative-pressure path 851 and opens the positive-pressure path 852. The white dashed arrow indicates a supply of the negative-pressure air and the black dashed arrow indicates a supply of the positive-pressure air.

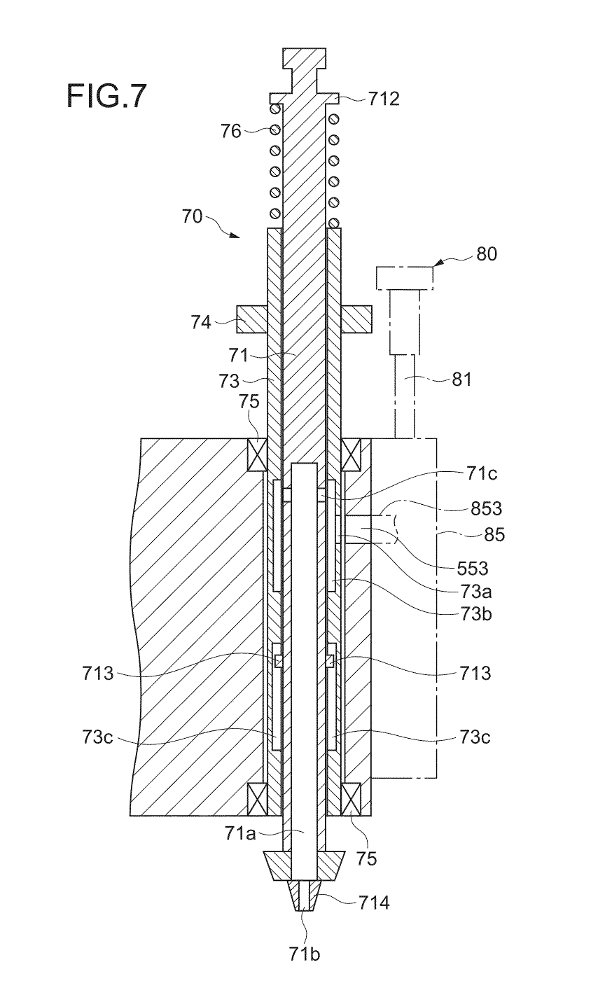

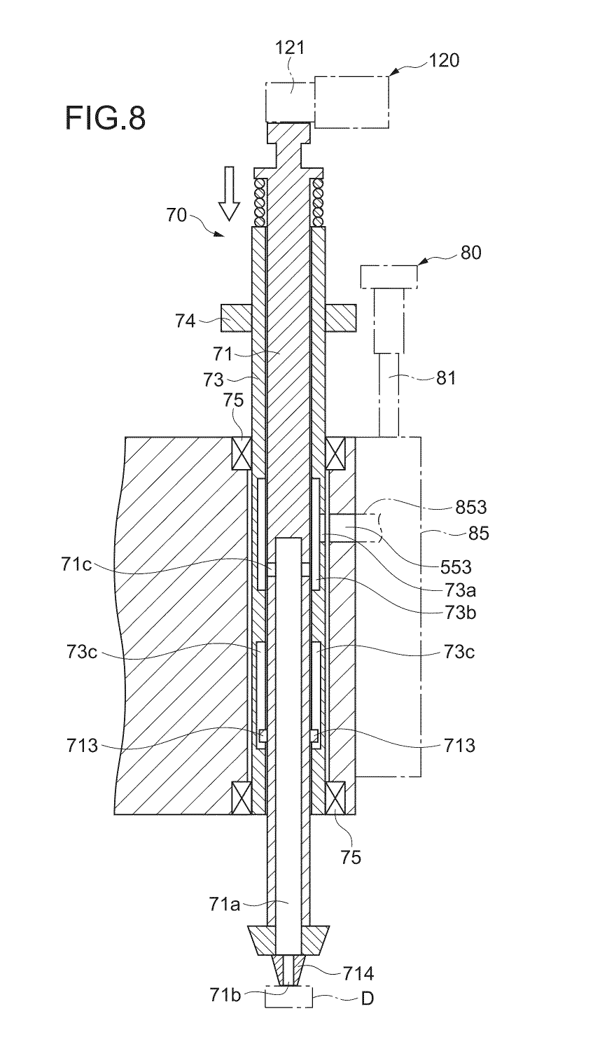

FIG. 7 is a cross-sectional view showing the nozzle unit 70 retained by the turret 50. FIG. 8 is a cross-sectional view showing a state in which the nozzle unit 70 moves downwards.

Referring to FIG. 7, the main body 55 of the turret 50 is provided with a communication path 553 formed by the outer peripheral surface 55b. The connection path 853 provided to the casing 85 of the valve mechanism 80 described above is in communication with the communication path 553 of the turret 50.

The nozzle unit 70 includes the nozzle 71 and a nozzle holder 73 covering an outer periphery of the nozzle 71. The nozzle holder 73 is, at both end portions of the nozzle holder 73, rotatably connected to the turret 50 via a bearing 75.

In an inner peripheral surface of the nozzle holder 73, an inner peripheral space 73b is provided over its entire periphery. An opening 73a communicating the inner peripheral space 73b with the communication path 553 of the turret 50 is formed penetrating through the nozzle holder 73. In an axial center portion of the nozzle 71, the actuating chamber 71a long in the axial direction (length direction of the nozzle 71) is formed. Further, a communication hole 71c communicating the inner peripheral space 73b of the nozzle holder 73 with the actuating chamber 71a of the nozzle 71 is formed penetrating through the nozzle 71.

With such a configuration, the connection path 853 of the casing 85 of the valve mechanism 80 is in communication with the actuating chamber 71a of the nozzle 71.

The actuating chamber 87 of the nozzle 71 is in communication with an outside through a hole 71b provided in a tip end portion 714 of the nozzle 71. The hole 71b of the tip end portion 714 has a size to retain an electronic component D smaller than a size of, for example, 1 mm*1 mm, as shown in FIG. 8. A plurality of holes 71b may be provided.

As shown in FIG. 7, a coil spring 76 is provided between a flange 712 formed in an upper portion of the nozzle 71 and an upper end of the nozzle holder 73. In the state shown in FIG. 7, the nozzle unit 70 is static, that is, the coil spring 76 is in a normal state.

In FIG. 8, the nozzle 71 is downwardly pushed by a pressing roller 121 of a nozzle driving unit 120 against the biasing force of the coil spring 76. The position of the communication hole 71c and the length of the inner peripheral space 73b in the axial direction are set such that the inner peripheral space 73b is in communication with the actuating chamber 87 even in the state in which the nozzle 71 moves downwards as shown in FIG. 8. As the nozzle driving unit 120, for example, a well-known mechanism as shown in Japanese Patent Application Laid-open No. 2005-150638 may be used.

In the nozzle holder 73, slit grooves 73c are formed to be long along the axial direction. The plurality of (e.g., two to four) slit grooves 73c are provided in the circumferential direction between the inner peripheral space 73b and the tip end portion 714 of the nozzle 71. However, the slit grooves 73c may be arranged at other positions.

A slide piece 713 is engaged to each of the slit grooves 73c to be slidable in the axial direction. With this, the nozzle 71 is allowed to move upwards and downwards with respect to the nozzle holder 73 and the nozzle 71 and the nozzle holder 73 are allowed to integrally rotate. Slit grooves 73c and slide pieces 713 may be provided at a plurality of positions in the axial direction.

The base shaft 35 and the turret 50 rotatably retain each of the nozzle units 70 as described above, by a mechanism that will be described in the following.

As shown in FIG. 4, an outer tube 40 is connected to the outer peripheral surface of the base shaft 35 between the position of the base shaft 35 supported by the upper support portion 32 and the position of the base shaft 35 to which the turret 50 is connected. The outer tube 40 is connected to the base shaft 35 via bearings 43 and 44 and rotatable with respect to the base shaft 35. For example, a rotational driving mechanism using a pulley and a belt (not shown) is connected to the outer tube 40. A collar 46 retaining the bearings 43 and 44 is provided, for example, between the base shaft 35 and the outer tube 40.

In a flange 40a formed at an end portion of the outer tube 40 on a side of the turret 50, the outer tube 40 and a large-diameter gear (engagement portion) 42 are fixed with bolts 41. With this, the outer tube 40 and the large-diameter gear 42 rotate integrally. The outer tube 40 and the large-diameter gear 42 function as a second rotating body.

As shown in FIG. 4, the large-diameter gear 42 meshes with a gear portion 74 (engagement portion) formed closer to an upper portion of the nozzle holder 73. Therefore, by rotating the outer tube 40, the nozzle holder 73 meshing with the large-diameter gear 42 is rotated. As shown in FIG. 7, the slide piece 713 is engaged to the slit groove 73c. Therefore, rotation of the nozzle holder 73 rotates the nozzle 71 together with the nozzle holder 73.

Note that, the engagement portion is not limited to the gear and any engagement portion may be employed as long as the engagement portion can generate torque to the nozzle unit 70.

As shown in FIG. 5, the gear portions 74 provided to the nozzle units 70 are arranged offsetting each other in length directions of the nozzle units 70. Typically, the gear portions 74 are arranged offsetting each other in a zigzag manner in the length direction. With this, arrangement density of the nozzle units 70 can be increased and downsizing of the mounting head unit 150 can be achieved.

The mounting head unit 150 according to this embodiment also exerts effects obtained by the apparatus of Patent Document 1 above.

### Operation of Mounting Head Unit

During the following operation of the mounting head unit 150, a negative-pressure source and a pressurizing mechanism (not shown) supply the negative-pressure air and the positive-pressure air into the negative-pressure paths and the positive-pressure paths of the base shaft 35 and the turret 50 through the negative-pressure supply path 32a and the positive-pressure supply path 33a of the support 30.

First, in the mounting area M of the conveyor unit 16, the substrate W is positioned and retained. By being moved in a horizontal plane by the X-axis movement mechanism and the Y-axis movement mechanism, the mounting head unit 150 moves to above the supply area S of electronic components.

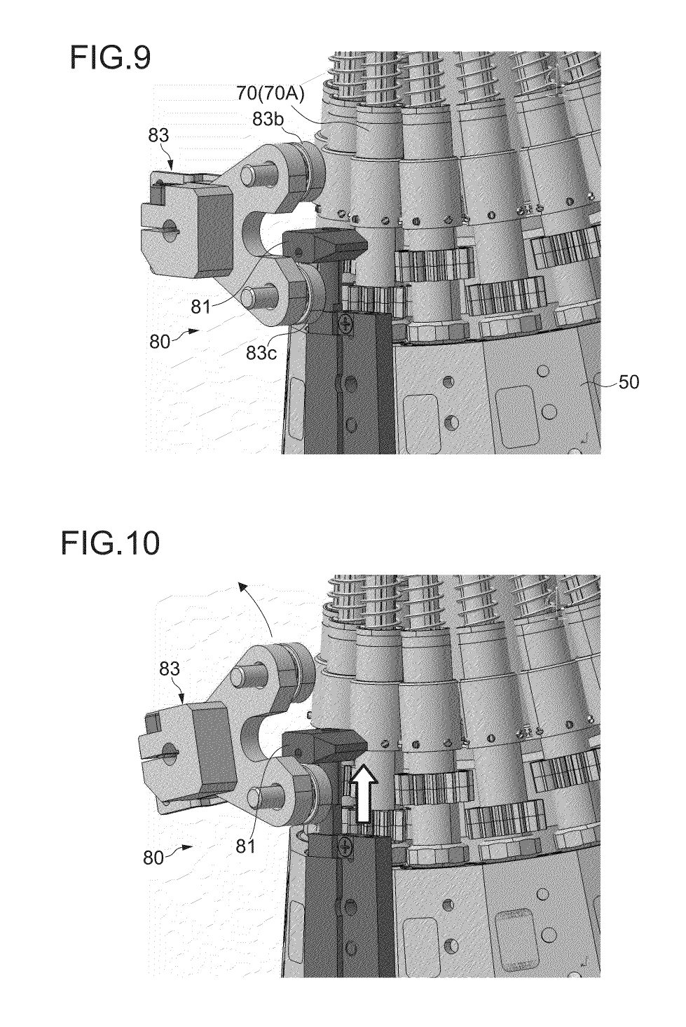

FIGS. 9 to 12 are views each showing an operation of the valve mechanism 80. The mounting head unit 150 moves to above the supply area S of the electronic components. Until an electronic component is taken out of the tape feeder 90, the valve lever 83 is located at a position not interfering with the valve main body 81 as shown in FIG. 9. This position is referred to as a stand-by position (initial position) of the valve lever 83. The state shown in FIG. 9 is, for example, a state in which the valve main body 81 moves downwards. That is, as shown in FIG. 6B, the positive-pressure path 852 is opened and the positive-pressure air is supplied into the nozzle unit 70A.

When the mounting head unit 150 arrives at the supply area S, as shown in FIG. 10, the valve lever 83 rotates from the stand-by position shown in FIG. 9 by a predetermined angle and lifts the valve main body 81. With this, the valve mechanism 80 is held in the state shown in FIG. 6A. In this state, the negative-pressure path 851 is opened and the negative-pressure air is supplied into the nozzle unit 70A. In the state in which the negative-pressure air is supplied into the nozzle unit 70A, the pressing roller 121 of the nozzle driving unit 120 (see FIG. 8) moves downwards and the nozzle 71 also moves downwards. Thus, an electronic component is sucked by negative-pressure force.

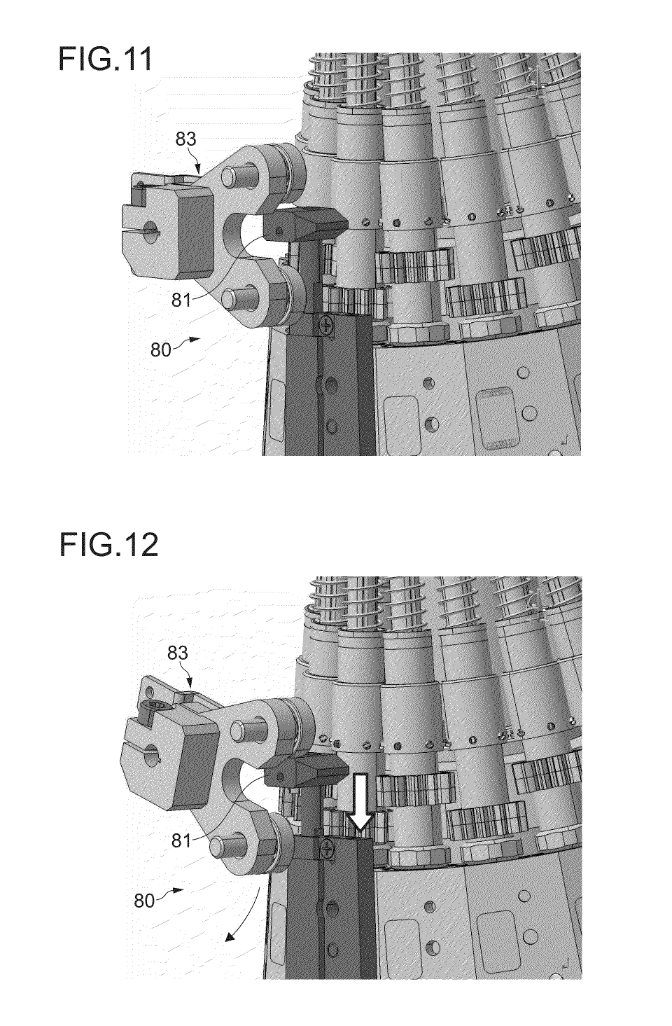

After the electronic component is sucked by the nozzle unit 70, the pressing roller 121 moves upwards and the nozzle 71 also moves upwards under the returning force of the coil spring 76. Further, while or after the nozzle 71 moves upwards, the valve lever 83 rotates from the state shown in FIG. 10 by a predetermined angle and returns to the stand-by position shown in FIG. 11 (rotational angle position of the valve lever 83 as in FIG. 9). However, the valve main body 81 is kept lifted under the frictional force between an inner peripheral surface of the actuating chamber 87 and the valve body 84.

Next, the mounting head unit 150 rotates the turret 50 by 30 degrees with the base shaft 35 being a center, selects a next (neighbor) nozzle unit 70, and positions that nozzle unit 70 to be along the vertical axis. Then, by the same operation as described above, the next electronic component is sucked and retained. In this manner, by repeating the operations shown in FIGS. 10 and 11 a number of times corresponding to the number of nozzle units 70 (or fewer than the number of nozzle units 70), the mounting head unit 150 causes each nozzle unit 70 to suck an electronic component.

Next, the mounting head unit 150 moves to above the mounting area M by the X-axis movement mechanism and the Y-axis movement mechanism. By the pressing roller 121 of the nozzle driving unit 120 (see FIG. 8) moving downwards, the nozzle 71 of the nozzle unit 70A selected among the plurality of nozzle units 70 moves downwards while being pressed by the pressing roller 121. The electronic component retained by the nozzle 71 is placed at a predetermined mounting position on the substrate W.

When the electronic component is placed on the substrate W, as shown in FIG. 12, the valve lever 83 rotates by a predetermined angle from the initial position shown in FIG. 11. With this, as shown in FIG. 6B, the positive-pressure path 852 is opened and the positive-pressure air is supplied into the nozzle 71. As a result, the electronic component is held in a state in which the electronic component can be separated from the tip end portion 714 of the nozzle 71 and the electronic component is attached (mounted) on the substrate W.

Alternatively, at the same time when or immediately before the electronic component retained by the nozzle 71 is placed at a predetermined mounting position on the substrate W, the valve lever 83 may be actuated such that the nozzle 71 is supplied with the positive-pressure air.

Next, in order to mount an electronic component retained by a different nozzle unit 70 on the substrate W, the mounting head unit 150 is moved by the X-axis movement mechanism and the Y-axis movement mechanism such that that different nozzle unit 70 is moved within the mounting area M. In the middle of or after movement, the valve lever 83 returns to the initial position (see FIG. 9), releases the interference between the valve lever 83 and the valve main body 81, and rotates the turret 50 to select the different nozzle unit 70A.

The mounting head unit 150 repeats the above-mentioned operations for mounting an electronic component a number of times corresponding to the number of nozzle units 70 (or the number of sucked electronic components).

When a predetermined number of electronic components are mounted on the substrate W in the above-mentioned manner, the substrate W is unloaded by the conveyor unit 16 to an outside of the component mounting apparatus 100.

In the head (tool head) described in Patent Document 1, the positive-pressure path and the negative-pressure path (flow paths) in a radial direction are individually formed within the base shaft, and hence those flow paths become narrower. If the positive-pressure path and the negative-pressure flow path are made wider in order to increase the flow rate of the air, the diameter size and the like of the base shaft becomes larger and the base shaft and a structure supporting the base shaft increase in size. Further, the tool head has a structure in which the positive-pressure air and the negative-pressure air are supplied from one end of the base shaft, and hence a mechanism for supporting the tool head has a cantilever structure.

In contrast, the negative-pressure path 351 and the positive-pressure path 352 in the mounting head unit 150 according to this embodiment are provided to be aligned with each other in the axial direction of the base shaft 35. Therefore, the negative-pressure air and the positive-pressure air can be supplied into the negative-pressure path 351 and the positive-pressure path 352 from the upper portion and the lower portion of the base shaft 35, respectively. That is, in this embodiment, unlike the related art, it is unnecessary to place a tubular member within the base shaft to separate the negative-pressure path from the positive-pressure path in the radial direction of the shaft. Therefore, the structure of the mounting head unit 150 according to this embodiment can be simplified.

In addition, the support 30 includes structures supporting the upper portion and the lower portion of the base shaft 35. That is, the support 30 does not have the cantilever supporting structure unlike the related art, and hence rigidity of the entire mounting head unit 150 can be enhanced. Thus, it is possible to reduce the backlash of the base shaft 35.

In other words, in this embodiment, by providing the support 30 with not the cantilever supporting structure but a both-end supporting structure and supplying the negative-pressure air and the positive-pressure air from the both ends of the base shaft 35, a simple, compact, and highly rigid structure of the mounting head unit 150 can be realized. Further, the negative-pressure supply path 32a and the positive-pressure supply path 33a are provided within the upper support portion 32 and the lower support portion 33 of the support 30, and hence the upper support portion 32 and the lower support portion 33 have a function of forming the flow paths in addition to the function of supporting the base shaft 35. With this, it is unnecessary to provide a separate flow-path forming member, and hence it is possible to reduce the number of components and downsize the mounting head unit 150. Further, that contributes to a cost reduction.

Further, by enhancing the rigidity of the mounting head unit 150, a small electronic component can be mounted on the substrate W with high position accuracy.

As described above, in this embodiment, the negative-pressure path 351 and the positive-pressure path 352 within the base shaft 35 are coaxially arranged. Therefore, the diameter of the base shaft 35 can be reduced.

In this embodiment, unlike the related art, the negative-pressure path and the positive-pressure path are formed in the radial direction. Therefore, it is possible to increase the flow path diameter of each of the negative-pressure path 351 and the positive-pressure path 352. Therefore, the flow rate of the negative-pressure air and the positive-pressure air can be increased.

For example, the flow rate of the negative-pressure air increases, and hence the retaining force of an electronic component by the nozzle unit 70 can be increased and movement speed of the mounting head unit 150 can be increased. As a result, the productivity is enhanced.

Further, the retaining force of the electronic component by the nozzle unit 70 can be increased. Therefore, it is possible to increase component suction rate, that is, to reduce a suction error and the rate of loss of components.

Further, the retaining force of the electronic component by the nozzle unit 70 can be enhanced. Therefore, it is possible to reduce a position error of electronic components sucked by the nozzle units 70 and to improve product quality.

In this embodiment, the base shaft 35 and the turret 50 are formed such that the total volume of the negative-pressure path 351 and the negative-pressure paths 551 within the base shaft 35 and the turret 50 becomes larger than the total volume of the positive-pressure path 352 and the positive-pressure paths 552. By using the flow path larger in volume as the negative-pressure flow path, it is easier to maintain the negative pressure in comparison with the case of using the flow path smaller in volume as the negative-pressure flow path.

If the positive pressure and the negative pressure are generated within the two flow paths having the same flow path volume, the positive pressure can be generated more easily than the negative pressure. That is, a faster response is obtained in the case where the positive pressure is generated in comparison with the case where the negative pressure is generated. That is because vacuuming needs to be performed for generating the negative pressure. Therefore, if the flow path volume of the negative pressure is set to be larger, the negative pressure is easily maintained after vacuuming of the flow path.

In this embodiment, by forming the tubular body 45 separate from the base shaft 35 and inserting the tubular body 45 into the base shaft 35, the negative-pressure path 351 and the positive-pressure path 352 are formed within the base shaft 35. This makes it easier to manufacture the base shaft 35 including the negative-pressure path and the positive-pressure path rather than forming the flow path separating the negative pressure from the positive pressure in the material of the base shaft 35. That is, in the case where the negative-pressure path and the positive-pressure path are formed in the material of the base shaft 35, it is necessary to form the partition in the material of the base shaft 35, and hence it is difficult to form the through-hole 35a in the base shaft 35. Rather than forming two holes for the positive pressure and the negative pressure in the base shaft 35, forming the through-hole 35a as in this embodiment makes it easier to manufacture the base shaft 35.

In addition, fitting the tubular body 45 to the positive-pressure side within the base shaft 35, that is, fitting the tubular body 45 from the smaller-volume flow path (flow path smaller in depth) to the base shaft 35 is easier than fitting the tubular body 45 from the larger-volume flow path (flow path larger in depth) to the base shaft 35.

Further, even if the tubular body 45 is provided on the positive-pressure side being a lower side of the base shaft 35 as in this embodiment, the tubular body 45 is pulled under the negative-pressure suction force from the negative-pressure side located above the positive-pressure side. That is, the tubular body 45 is unlikely to be pulled out of the through-hole 35a of the base shaft 35, which is advantageous.

### Configuration of Mounting Head Unit According to Second Embodiment

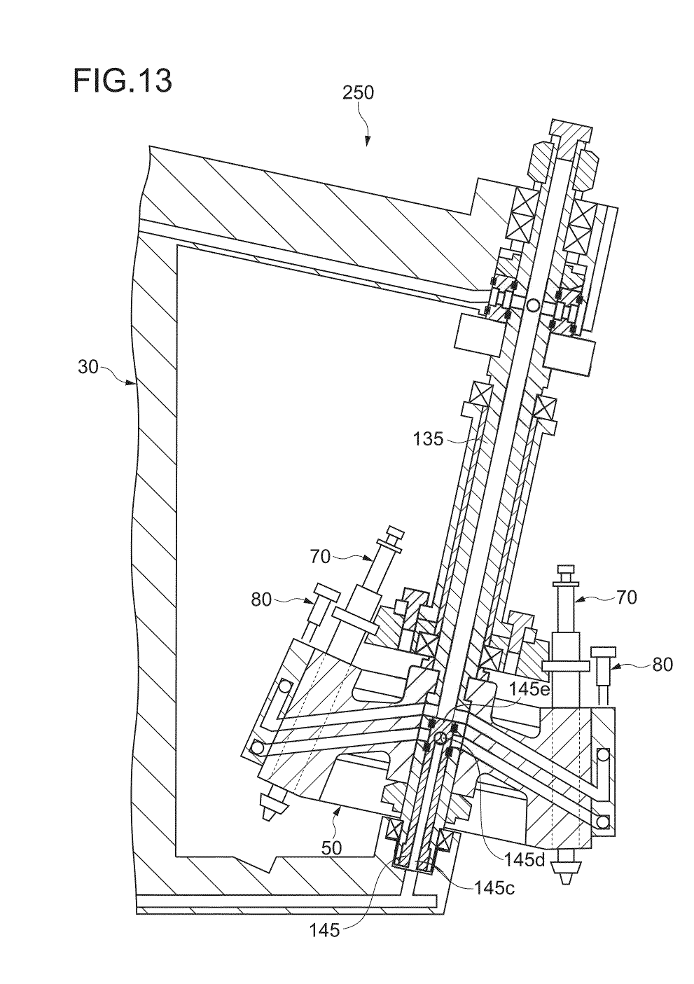

FIG. 13 is a cross-sectional view showing a configuration of a mounting head unit according to a second embodiment. A difference between the mounting head unit 250 according to the second embodiment and the mounting head unit 150 according to the first embodiment is a structure of a tubular body 145 provided within a base shaft 135.

The tubular body 145 is not opened at one end portion thereof and includes a closed end 145e. The tubular body 145 includes an axial positive-pressure flow path 145c and a radial positive-pressure flow path 145d. The closed end 145e corresponds to the partition 45f. Also with this configuration, the same effect as that of the first embodiment can be obtained.

### Other Embodiments

The present disclosure is not limited to the above-mentioned embodiments and various other modifications may be made.

In the above-mentioned embodiments, the air is used as the gas. However, other gas such as inert gas may be used.

As the non-negative-pressure gas, positive-pressure gas (positive-pressure air) having a pressure higher than the atmospheric pressure is used. However, gas having a pressure substantially equal to the atmospheric pressure may be used.

In the above-mentioned embodiments, the negative-pressure path within the base shaft 35 has a volume larger than the volume of the positive-pressure path. However, the negative-pressure path within the base shaft may have volume smaller than the volume of the positive-pressure path. Alternatively, the negative-pressure path within the base shaft may have volume equal to the volume of the positive-pressure path.

In the above-mentioned embodiments, the negative-pressure path is formed on the upper side of the base shaft 35 and the positive-pressure path is formed on the lower side. However, the negative-pressure path may be formed on the lower side of the base shaft and the non-negative-pressure path may be formed on the upper side.

In the above-mentioned embodiments, due to the provision of the tubular body 45 within the base shaft 35, the negative-pressure path and the positive-pressure path are formed. However, the negative-pressure path and the positive-pressure path may be formed in the material of the base shaft.

In the above-mentioned embodiments, the base shaft 35 is provided while being inclined with respect to the vertical axis. However, the base shaft 35 may be provided along the vertical axis. In this case, the plurality of nozzle units 70 may also be provided with the length direction of the nozzle units 70 being along the vertical axis.

The structures of the turret 50, the valve mechanisms 80, the nozzle units 70, and the like are not limited to those according to the above-mentioned embodiments and a design change may be appropriately made. For example, the air flow paths in the turret 50 and the valve mechanisms 80 may also be appropriately changed.

Although the gear portions 74 of the nozzle units 70 according to the above-mentioned embodiments are arranged one by one in a zigzag manner in the length direction, that is, to be upper, lower, upper, lower, . . . , the arrangement of the gear portions 74 is not limited thereto. The gear portions 74 may be arranged in three height stages in the length direction, specifically, to be upper, middle, lower, upper, middle, lower, . . . or to be upper, middle, lower, middle, upper, . . . in the length directions of the nozzle units 70.

In the above-mentioned embodiments, the mounting head unit 150 moves in the plane (X-Y plane) substantially parallel to the mounting surface of the substrate W upon mounting of the electronic components. However, the substrate W may move in the plane. Alternatively, both of the mounting head unit 150 and the substrate W may move in the plane.

Out of the features of each embodiment described above, at least two features may be combined.

It should be noted that the present disclosure may also take the following configurations.
(1) A mounting head unit, including:

a rotating body including
a rotating shaft,
a negative-pressure path that is provided within the rotating shaft and configured to flow negative-pressure gas therethrough,
a non-negative-pressure path that is configured to flow non-negative-pressure gas therethrough and provided within the rotating shaft to be aligned with the negative-pressure path in an axial direction of the rotating shaft, and
a partition that is provided within the rotating shaft and configured to separate the negative-pressure path from the non-negative-pressure path;

a nozzle that includes a flow path configured to flow gas therethrough, is connected to the rotating body such that the flow path is in communication with the negative-pressure path and the non-negative-pressure path of the rotating body, and configured to be capable of sucking a component by being supplied with the negative-pressure gas from the negative-pressure path; and

a valve mechanism configured to switch between a negative-pressure state and a non-negative-pressure state of the gas to be supplied into the nozzle.
(2) The mounting head unit according to (1), in which

the rotating shaft of the rotating body includes
a first end portion, and
a second end portion on an opposite side of the first end portion, and

the mounting head unit further includes a support configured to integrally support the first end portion and the second end portion of the rotating shaft.
(3) The mounting head unit according to (2), in which

the support includes
a first support portion that includes a supply path of the negative-pressure gas and is connected to the first end portion of the rotating shaft, the supply path of the negative-pressure gas being in communication with the negative-pressure path of the rotating shaft, and
a second support portion that includes a supply path of the non-negative-pressure gas and is connected to the second end portion of the rotating shaft, the supply path of the non-negative-pressure gas being in communication with the non-negative-pressure path of the rotating shaft.
(4) The mounting head unit according to (3), in which

the rotating body is formed such that the negative-pressure path has a volume larger than a volume of the non-negative-pressure path.
(5) The mounting head unit according to (4), in which

the rotating shaft of the rotating body includes a through-hole along the axial direction of the rotating shaft, and

the rotating body further includes a tubular body including the partition, the tubular body being located to be closer to the first end portion than the second end portion within the through-hole of the rotating shaft.
(6) The mounting head unit according to (1) or (2), in which

the rotating body is formed such that the negative-pressure path has a volume larger than a volume of the non-negative-pressure path.
(7) The mounting head unit according to any one of (1) to (6), in which

the negative-pressure path and the non-negative-pressure path are coaxially arranged.
(8) The mounting head unit according to any one of (1) to (7), in which

the valve mechanism includes
a casing that includes a connection path that is connected to the negative-pressure path and the non-negative-pressure path and capable of supplying the negative-pressure gas and the non-negative-pressure gas to the nozzle, the casing being connected to the rotating body, and
a valve body that is provided within the casing and configured to switch between communication of the negative-pressure path with the connection path of the casing and communication of the non-negative-pressure path with the connection path.
(9) The mounting head unit according to any one of (1) to (8), further including

a second rotating body that includes an engagement portion and is rotatably connected to an outer peripheral portion of the rotating shaft, in which

the rotating body includes an engagement portion that is engaged to the engagement portion of the second rotating body and is configured to retain the nozzle to be rotatable by rotation of the second rotating body.
(10) The mounting head unit according to (9), further including

a plurality of nozzles, in which

the engagement portion includes a plurality of engagement portions respectively provided for the plurality of nozzles, the plurality of engagement portions offsetting each other in length directions of the plurality of nozzles.
(11) The mounting head unit according to any one of (1) to (10), in which

the rotating body includes a turret configured to support a plurality of nozzles, the turret including part of each of the non-negative-pressure path and the negative-pressure path and being provided to an end portion of the rotating shaft.
(12) A component mounting apparatus, including:

a retaining unit configured to retain a substrate;

a rotating body including
a rotating shaft,
a negative-pressure path that is provided within the rotating shaft and configured to flow negative-pressure gas therethrough,
a non-negative-pressure path that is configured to flow non-negative-pressure gas therethrough and provided within the rotating shaft to be aligned with the negative-pressure path in an axial direction of the rotating shaft, and
a partition that is provided within the rotating shaft and configured to separate the negative-pressure path from the non-negative-pressure path;

a nozzle that includes a flow path configured to flow gas therethrough, is connected to the rotating body such that the flow path is in communication with the negative-pressure path and the non-negative-pressure path of the rotating body, and configured to be capable of sucking a component by being supplied with the negative-pressure gas from the negative-pressure path and to mount the sucked component on the substrate retained by the retaining unit by being supplied with the non-negative-pressure gas from the non-negative-pressure path; and

a valve mechanism configured to switch between a negative-pressure state and a non-negative-pressure state of the gas to be supplied into the nozzle.
(13) A method of manufacturing a substrate by a component mounting apparatus including a retaining unit configured to retain a substrate and a mounting head unit configured to mount a component on the substrate, the mounting head unit including

a rotating body including
a rotating shaft,
a negative-pressure path that is provided within the rotating shaft and configured to flow negative-pressure gas therethrough,
a non-negative-pressure path that is configured to flow non-negative-pressure gas therethrough and provided within the rotating shaft to be aligned with the negative-pressure path in an axial direction of the rotating shaft, and
a partition that is provided within the rotating shaft and configured to separate the negative-pressure path from the non-negative-pressure path,

a nozzle that includes a flow path configured to flow gas therethrough and is connected to the rotating body such that the flow path is in communication with the negative-pressure path and the non-negative-pressure path of the rotating body, and

a valve mechanism configured to switch between a negative-pressure state and a non-negative-pressure state of the gas to be supplied into the nozzle, the method including:

sucking the component by the nozzle supplied with the negative-pressure gas from the negative-pressure path; and

mounting the sucked component on the substrate retained by the retaining unit, by supplying the non-negative-pressure gas from the non-negative-pressure path to the nozzle.

The present disclosure contains subject matter related to that disclosed in Japanese Priority Patent Application JP 2012-041130 filed in the Japan Patent Office on Feb. 28, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A mounting head unit, comprising:
a rotating body including
a rotating shaft,
a negative-pressure path that is provided within the rotating shaft and configured to flow negative-pressure gas therethrough,
a non-negative-pressure path that is configured to flow non-negative-pressure gas therethrough and provided within the rotating shaft to be aligned with the negative-pressure path in an axial direction of the rotating shaft, and
a partition that is provided within the rotating shaft and configured to separate the negative-pressure path from the non-negative-pressure path;
a nozzle that includes a flow path configured to flow gas therethrough, is connected to the rotating body such that the flow path is in communication with the negative-pressure path and the non-negative-pressure path of the rotating body, and configured to be capable of sucking a component by being supplied with the negative-pressure gas from the negative-pressure path; and
a valve mechanism configured to switch between a negative-pressure state and a non-negative-pressure state of the gas to be supplied into the nozzle.

2. The mounting head unit according to claim 1, wherein
the rotating shaft of the rotating body includes
a first end portion, and
a second end portion on an opposite side of the first end portion, and
the mounting head unit further includes a support configured to integrally support the first end portion and the second end portion of the rotating shaft.

3. The mounting head unit according to claim 2, wherein
the support includes
a first support portion that includes a supply path of the negative-pressure gas and is connected to the first end portion of the rotating shaft, the supply path of the negative-pressure gas being in communication with the negative-pressure path of the rotating shaft, and
a second support portion that includes a supply path of the non-negative-pressure gas and is connected to the second end portion of the rotating shaft, the supply path of the non-negative-pressure gas being in communication with the non-negative-pressure path of the rotating shaft.

4. The mounting head unit according to claim 3, wherein
the rotating body is formed such that the negative-pressure path has a volume larger than a volume of the non-negative-pressure path.

5. The mounting head unit according to claim 4, wherein
the rotating shaft of the rotating body includes a through-hole along the axial direction of the rotating shaft, and
the rotating body further includes a tubular body including the partition, the tubular body being located to be closer to the first end portion than the second end portion within the through-hole of the rotating shaft.

6. The mounting head unit according to claim 1, wherein
the rotating body is formed such that the negative-pressure path has a volume larger than a volume of the non-negative-pressure path.

7. The mounting head unit according to claim 1, wherein
the negative-pressure path and the non-negative-pressure path are coaxially arranged.

8. The mounting head unit according to claim 1, wherein
the valve mechanism includes
a casing that includes a connection path that is connected to the negative-pressure path and the non-negative-pressure path and capable of supplying the negative-pressure gas and the non-negative-pressure gas to the nozzle, the casing being connected to the rotating body, and
a valve body that is provided within the casing and configured to switch between communication of the negative-pressure path with the connection path of the casing and communication of the non-negative-pressure path with the connection path.

9. The mounting head unit according to claim 1, further comprising
a second rotating body that includes an engagement portion and is rotatably connected to an outer peripheral portion of the rotating shaft, wherein
the rotating body includes an engagement portion that is engaged to the engagement portion of the second rotating body and is configured to retain the nozzle to be rotatable by rotation of the second rotating body.

10. The mounting head unit according to claim 9, further comprising
a plurality of nozzles, wherein
the engagement portion includes a plurality of engagement portions respectively provided for the plurality of nozzles, the plurality of engagement portions offsetting each other in length directions of the plurality of nozzles.

11. The mounting head unit according to claim 1, wherein
the rotating body includes a turret configured to support a plurality of nozzles, the turret including part of each of the non-negative-pressure path and the negative-pressure path and being provided to an end portion of the rotating shaft.

12. A component mounting apparatus, comprising:
a retaining unit configured to retain a substrate;
a rotating body including
a rotating shaft,
a negative-pressure path that is provided within the rotating shaft and configured to flow negative-pressure gas therethrough,
a non-negative-pressure path that is configured to flow non-negative-pressure gas therethrough and provided within the rotating shaft to be aligned with the negative-pressure path in an axial direction of the rotating shaft, and
a partition that is provided within the rotating shaft and configured to separate the negative-pressure path from the non-negative-pressure path;
a nozzle that includes a flow path configured to flow gas therethrough, is connected to the rotating body such that the flow path is in communication with the negative-pressure path and the non-negative-pressure path of the rotating body, and configured to be capable of sucking a component by being supplied with the negative-pressure gas from the negative-pressure path and to mount the sucked component on the substrate retained by the retaining unit by being supplied with the non-negative-pressure gas from the non-negative-pressure path; and
a valve mechanism configured to switch between a negative-pressure state and a non-negative-pressure state of the gas to be supplied into the nozzle.

13. A method of manufacturing a substrate by a component mounting apparatus including a retaining unit configured to retain a substrate and a mounting head unit configured to mount a component on the substrate, the mounting head unit including
a rotating body including
a rotating shaft,
a negative-pressure path that is provided within the rotating shaft and configured to flow negative-pressure gas therethrough,
a non-negative-pressure path that is configured to flow non-negative-pressure gas therethrough and provided within the rotating shaft to be aligned with the negative-pressure path in an axial direction of the rotating shaft, and
a partition that is provided within the rotating shaft and configured to separate the negative-pressure path from the non-negative-pressure path,
a nozzle that includes a flow path configured to flow gas therethrough and is connected to the rotating body such that the flow path is in communication with the negative-pressure path and the non-negative-pressure path of the rotating body, and
a valve mechanism configured to switch between a negative-pressure state and a non-negative-pressure state of the gas to be supplied into the nozzle, the method comprising:
sucking the component by the nozzle supplied with the negative-pressure gas from the negative-pressure path; and
mounting the sucked component on the substrate retained by the retaining unit, by supplying the non-negative-pressure gas from the non-negative-pressure path to the nozzle.
